(19) United States
(12) Patent Application Publication
(10) Pub. No.: US 2009/0032970 A1
(43) Pub. Date: Feb. 5, 2009

(54) STACKING OF INTEGRATED CIRCUITS USING GLASSY METAL BONDING

(76) Inventors: Chang-Min Park, Portland, OR (US); Daewoong Suh, Phoenix, AZ (US)

Correspondence Address: COOL PATENT, P.C.;c/o INTELLEVATE, P.O. BOX 52050, MINNEAPOLIS, MN, 55402, US

(21) Appl. No.: 11/831,158

(22) Filed: Jul. 31, 2007

(51) Int. Cl. H01L 21/30; H01L 23/48

(52) U.S. Cl. 257/777; 438/455; 257/E23.01; 257/E21.211

(57) ABSTRACT

Techniques associated with stacking integrated circuits using glassy metal bonding are generally described. In one example, an apparatus includes a first integrated circuit having one or more bonding pads and a second integrated circuit having one or more bonding pads, the second integrated circuit being electrically and mechanically coupled with the first integrated circuit by one or more joints formed between the one or more bonding pads of the first and second integrated circuit using a bulk metallic glass bonding material, wherein the bulk metallic glass material provides a low temperature and low pressure bonding solution to reduce delamination or wherein the bulk metallic glass provides reduced intermetallic compound to increase joint reliability, or suitable combinations thereof.

### TECHNICAL FIELD

Embodiments disclosed herein are generally directed to the field of semiconductor fabrication and, more particularly, to stacking of integrated circuits.

### BACKGROUND

Generally, stacked integrated circuits such as stacked memory devices and/or three dimensional interconnects are used to provide larger storage volume or processing capacity while using cheaper, lower density manufacturing designs. Currently, wafers may be stacked by bonding Cu pads of two integrated circuits together using temperatures in excess of about 200° C. at pressures exceeding about 40 kN. Such thermal bonding process may require heating and cooling of separate wafers/dies resulting in poor bonding qualities during post-bonding processes. Exposure to high temperature and/or heating and cooling of separate wafers/dies may affect the quality and uniformity of a metallic bonding surface leading to problems such as delamination. Furthermore, current metallic bonding may form relatively brittle intermetallic compounds at the interface, which are typically a source of a host of reliability issues such as drop or shock failures.

### BRIEF DESCRIPTION OF THE DRAWINGS

Embodiments disclosed herein are illustrated by way of example, and not by way of limitation, in the figures of the accompanying drawings in which like reference numerals refer to similar elements and in which:

FIG. 1 is a process schematic for forming stacked integrated circuits, according to but one embodiment;

FIG. 2 is a flow diagram of a method for stacking integrated circuits, according to but one embodiment; and

FIG. 3 is a diagram of an example system in which embodiments of the present invention may be used, according to but one embodiment.

It will be appreciated that for simplicity and/or clarity of illustration, elements illustrated in the figures have not necessarily been drawn to scale. For example, the dimensions of some of the elements may be exaggerated relative to other elements for clarity. Further, if considered appropriate, reference numerals have been repeated among the figures to indicate corresponding and/or analogous elements.

### DETAILED DESCRIPTION

Embodiments of stacking integrated circuits using glassy metal bonding are described herein. In the following description, numerous specific details are set forth to provide a thorough understanding of embodiments disclosed herein. One skilled in the relevant art will recognize, however, that the embodiments disclosed herein can be practiced without one or more of the specific details, or with other methods, components, materials, and so forth. In other instances, well-known structures, materials, or operations are not shown or described in detail to avoid obscuring aspects of the specification.

Reference throughout this specification to “one embodiment” or “an embodiment” means that a particular feature, structure or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

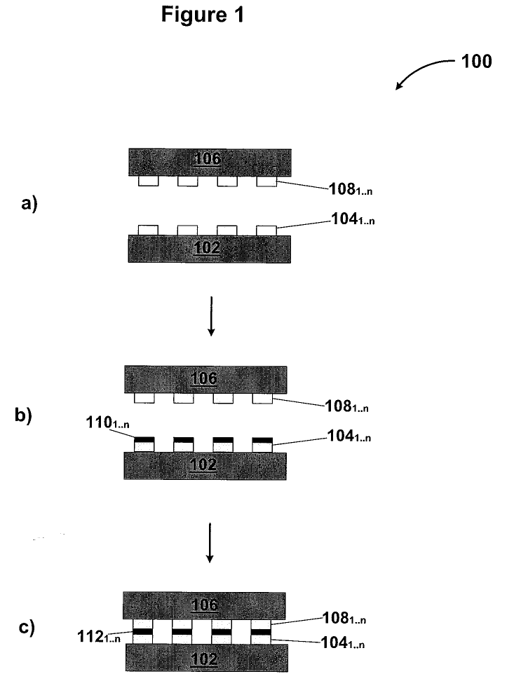

FIG. 1 is a process schematic for forming stacked integrated circuits 100, according to but one embodiment. In an embodiment, FIG. 1a includes a first integrated circuit 102, one or more bonding pads 104_{1 . . . n} coupled with the first integrated circuit 102, a second integrated circuit 106, and one or more bonding pads 108_{1 . . . n} coupled with the second integrated circuit 106, each coupled as shown. In an embodiment, FIG. 1b includes bulk metallic glass 110_{1 . . . n} coupled with the one or more bonding pads 104_{1 . . . n} of the first integrated circuit 102, as shown. In alternative embodiments of FIG. 1b, a bulk metallic glass 110_{1 . . . n} is applied to one or more bonding pads 108_{1 . . . n} of a second integrated circuit 106 or to the bonding pads 104_{1 . . . n}, 108_{1 . . . n} of both a first 102 and second 106 integrated circuit. In an embodiment, FIG. 1c includes one or more joints 112_{1 . . . n} formed using bulk metallic glass to join the first 102 and second 106 integrated circuits into a stacked microelectronic apparatus by applying heat and pressure, the joints 112_{1 . . . n} being coupled with the first 102 and second 106 integrated circuits through the bonding pads 104_{1 . . . n}, 108_{1 . . . n} as shown.

Bulk glassy metals or bulk metallic glasses 110_{1 . . . n}, 112_{1 . . . n} are materials that may exhibit both metallic properties (i.e.—electrical, thermal conduction, and high strength/toughness) and polymeric properties (i.e.—glass transition, thermoplastic behavior above glass transition temperature, T_{g}). Bulk glassy metals 110_{1 . . . n}, 112_{1 . . . n} may exhibit exceptional glass forming ability and thermal stability similar to polymers. Such glassy metals 110_{1 . . . n}, 112_{1 . . . n} may be amorphous in the solid state and become viscous liquid above T_{g}. In an embodiment, glassy metals 110_{1 . . . n}, 112_{1 . . . n} have unique rheological behavior above T_{g} that enables excellent formability and pattern replication ability on the scale of nanometers. In an embodiment, a bulk glassy metal 110_{1 . . . n}, 112_{1 . . . n} is amenable to polymer-like processing such as injection molding.

Because of their excellent pattern replication ability, bulk glassy metals 110_{1 . . . n}, 112_{1 . . . n} may have good adhesion on a variety of materials through nanometer scale interlocking without intermetallic compound formation. In other words, adhesion of bulk glassy metal 110_{1 . . . n}, 112_{1 . . . n} with other materials may not rely on intermetallic compound. The absence of intermetallic compound in bonding applications may be highly beneficial because intermetallic compounds are the source of reliability issues such as drop or shock failure in current microelectronic joints. Joints 112_{1 . . . n} formed using bulk metallic glass may provide a benefit of creating substantially no reliability-threatening intermetallic compounds at the interface between the joints 112_{1 . . . n} and the one or more pads 104_{1 . . . n},108_{1 . . . n} of the first 102 and second 106 integrated circuits. Reliability-threatening intermetallic compounds may include those compounds at the joint 112_{1 . . . n} interface that are more brittle relative to the rest of the joint.

Glassy metal 110_{1 . . . n}, 112_{1 . . . n} bonding may enable low temperature bonding between integrated circuits 102, 106. For example, a first 102 and second 106 integrated circuit may be thermoplastically bonded using glassy metal 110_{1 . . . n} as a bond layer at temperatures above T_{g}, the glass transition temperature, but below Tₘ, the melting temperature of the glassy metal 110_{1 . . . n}.

A sufficient amount of thermal energy applied to a bulky glass metal over a period of time may crystallize the material due to the metastability of bulky glass metals above T_{g}. Various stages of crystallization may be achieved in a bulky glass metal 112_{1 . . . n} including the onset of crystallization, partial crystallization in terms of %, or complete crystallization. In an embodiment, a bulky glass metal bonding material 110_{1 . . . n} is raised above T_{g} whereupon it is converted from a solid state glass to a viscous liquid. Above T_{g}, a liquid bulky glass metal 110_{1 . . . n} may be a supercooled liquid. In an embodiment, a bonding temperature for a first 102 and second 106 integrated circuit is above T_{g} and below Tₘ of a selected bulk metallic glass 110_{1 . . . n} such that thermoplastic bonding occurs within this temperature regime.

Thermoplastic bonding may also include the application of a low pressure. A low pressure may be provided by applying opposing force that is about normal to each planar backside surface of the first 102 and second 106 integrated circuits, the force being applied in a direction that tends to bring the first 102 and second 106 integrated circuits together. The backside of an integrated circuit 102, 106 may be a surface that does not have microcircuitry on the surface itself (i.e.—the planar surfaces opposite the pads 104_{1 . . . n}, 108_{1 . . . n}).

In an embodiment, the bonding temperature for the bulk metallic glass joint 112_{1 . . . n} is less than about 200° C. and the bonding pressure is less than about 40 kN. In an embodiment, the bonding temperature is about 100° C. or below according to the composition of the bulk metallic glass 110_{1 . . . n}. In an embodiment, the bonding pressure is about 1 MPa. Bonding temperature and pressure may vary or be different for different-sized wafers and dies and/or selected bulk glassy metals 110_{1 . . . n}.

A time period for thermoplastic bonding, annealing, or crystallization may be selected for a given temperature using a time-temperature-transformation diagram for the bulk glassy metal 110_{1 . . . n}, 112_{1 . . . n}. In an embodiment, a bulk glassy metal 110_{1 . . . n} bonding material is brought above its T_{g} and held at a selected temperature under low pressure for thermoplastic bonding for a selected time, the selected time being determinative of the amorphous and/or crystalline nature of a final glassy metal joint 112_{1 . . . n}. The bulk glassy metal joint 112_{1 . . . n} may be cooled down to room temperature after thermoplastic bonding or after any crystallization that may have occurred according to the selected time, temperature, and pressure for a given bulk glassy metal 110_{1 . . . n}, 112_{1 . . . n}.

In an embodiment, the bulk metallic glass joints 112_{1 . . . n} are amorphous, crystalline, or suitable combinations thereof. In an embodiment, the bulk metallic glass 112_{1 . . . n} becomes crystalline to provide stability and reliability. In another embodiment, the bulk metallic glass 112_{1 . . . n} remains in glass form. The operating temperatures of the stacked integrated circuits 102, 106 at the bulk metallic glass joint 112_{1 . . . n} and the T_{g} of the bulk metallic glass 112_{1 . . . n} may influence whether or not the joints 112_{1 . . . n} are desirably crystalline or amorphous. For example, a bulk metallic glass joint 112_{1 . . . n} with a very low T_{g} may be crystalline to avoid reaching the glass transition temperature (T_{g}) during operation of the stacked device. Reaching or exceeding the T_{g} for an amorphous joint 112_{1 . . . n} may compromise reliability by enabling liquid flow characteristics in the joint 112_{1 . . . n}.

In an embodiment, the bulk metallic glass joints 112_{1 . . . n} include materials such as Au_{49.2}Cu₂₇Ag_{5.5}Pd_{2.35}Si₁₆, Pt_{57.5}Cu_{14.7}Ni_{5.3}P_{22.5}, or Mg₆₅Cu₂₅Y₁₀, or suitable combinations thereof, where the numbers represent approximate atomic %. In an embodiment, Au_{49.2}Cu₂₇Ag_{5.5}Pd_{2.35}Si₁₆ has a T_{g} of about 128° C. and a suitable bonding temperature of about 160° C. to about 170° C. Other suitable glassy metals may be selected that accord with temperature and/or pressure embodiments described herein beyond the example materials listed above. Such glassy metals also fall within the scope and spirit of this specification.

In an embodiment, the first 102 and second 106 integrated circuits are in wafer form or die form. A wafer may be a circular semiconductor substrate upon which integrated circuits 102, 106 are formed with typical wafers being about 150 mm, 200 mm, or 300 mm in diameter. A die may be a rectangular portion on a wafer upon which one or more integrated circuits 102, 106 are formed. A wafer may be cut into one or more dies when the wafer is cut into individual product units. In an embodiment, the first 102 and second 106 integrated circuits include stacked wafers, dies, or suitable combinations thereof In another embodiment, a first 102 or second 106 integrated circuit may be a memory or logic device, or any suitable combination thereof.

In an embodiment, an apparatus according to FIG. 1c includes a first integrated circuit 102 having one or more bonding pads 104_{1 . . . n}, and a second integrated circuit 106 having one or more bonding pads 108_{1 . . . n}, the second integrated circuit 106 being electrically and mechanically coupled with the first integrated circuit by one or more joints 112_{1 . . . n} formed between the one or more bonding pads 104_{1 . . . n}, 108_{1 . . . n} of the first 102 and second 106 integrated circuits using a bulk metallic glass bonding material. In an embodiment, the bulk metallic glass joints 112_{1 . . . n} provide a low temperature and low pressure bonding solution to reduce delamination. In another embodiment, the bulk metallic glass joints 112_{1 . . . n} provides reduced intermetallic compound to increase joint reliability, or suitable combinations thereof.

In an embodiment according to FIG. 1c, the first 102 and second 106 integrated circuits are substantially aligned to enable electrical communication through the one or more joints 112_{1 . . . n} of a stacked apparatus. Materials for bulk metallic glass 110_{1 . . . n}, 112_{1 . . . n} may be selected for conductivity and/or other electrical properties that enable electrical signals to pass through the coupled bond pads 104_{1 . . . n}, 108_{1 . . . n}.

In another embodiment, the one or more pads 104_{1 . . . n}, 108_{1 . . . n} include Cu bond pads. Other suitable bonding pad 104_{1 . . . n}, 108_{1 . . . n} materials compatible with glassy metal bonding 112_{1 . . . n} may be used as well. The one or more bonding pads 104_{1 . . . n}, 108_{1 . . . n} may be on the order of microns or nanometers in size. For example, bonding pads 104_{1 . . . n}, 108_{1 . . . n} may be about 5-10 microns in size in an embodiment. Many more pads 104_{1 . . . n}, 108_{1 . . . n} may be bonded together than depicted in FIG. 1, which depicts only eight pads 104_{1 . . . n}, 108_{1 . . . n} for the sake of clarity and convenience. In an embodiment, the bonding pads 104_{1 . . . n}, 108_{1 . . . n} are patterned onto the surface of an integrated circuit 102, 106 using a bonding template layer pattern that defines at least the pitch and size of the pads 104_{1 . . . n}, 108_{1 . . . n}.

In other embodiments, one or more integrated circuits (not shown) in addition to the first 102 and second 106 integrated circuits are stacked together with the first 102 and second 106 integrated circuits using bulk metallic glass as a bonding material 112_{1 . . . n}.

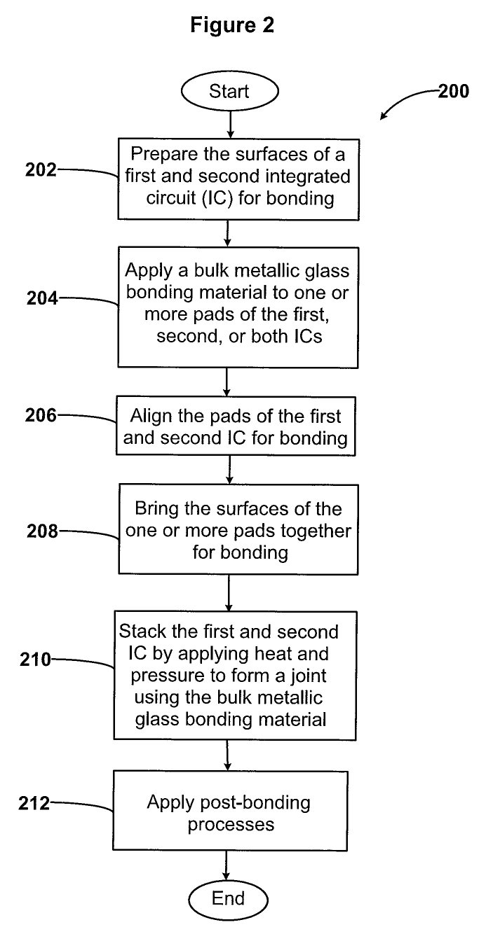

FIG. 2 is a flow diagram of a method for stacking integrated circuits 200, according to but one embodiment. In an embodiment, a method 200 includes preparing the surfaces of a first and second integrated circuit for bonding 202, applying a bulk metallic glass bonding material to one or more pads of the first, second, or both integrated circuits 204, aligning the pads of the first and second integrated circuit for bonding 206, bringing the surfaces of the one or more pads together for bonding 208, stacking the first and second integrated circuit by applying heat and pressure to form a joint using the bulk metallic glass bonding material 210, and applying post-bonding processes 212, with arrows providing a suggested flow.

Various operations may be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

In an embodiment, a method 200 includes applying a bulk metallic glass bonding material to one or more pads of a first integrated circuit or a second integrated circuit 204 wherein the bulk metallic glass bonding material provides a low temperature and low pressure bonding solution to reduce delamination or wherein the bulk metallic glass provides reduced intermetallic compound to increase joint reliability, or suitable combinations thereof. In another embodiment, applying a bulk metallic glass bonding material 204 includes applying materials such as Au_{49.2}Cu₂₇Ag_{5.5}Pd_{2.35}Si₁₆, Pt_{57.5}Cu_{14.7}Ni_{5.3}P_{22.5}, or Mg₆₅Cu₂₅Y₁₀, or suitable combinations thereof, where the numbers represent approximate atomic %.

In an embodiment, the bonding pads include Cu materials. In an embodiment, the pads are formed by creating a bond layer template pattern, which may be a Cu patterned layer on which glassy metal is applied 204. A glassy metal may be applied onto the template pattern 204, according to an embodiment.

In an embodiment, stacking the first and second integrated circuits 210 includes using a bonding temperature that is less than about 200° C. and applying a bonding pressures that is less than about 40 kN. In another embodiment, stacking the first and second integrated circuits 210 includes forming a bulk metallic glass joint having substantially no reliability-threatening intermetallic compounds at the interface between the joint and the one or more pads of the first and second integrated circuits.

In an embodiment, aligning the one or more pads 206 and bringing the surfaces of the pads together 208 for bonding is accomplished on a single piece of semiconductor manufacturing equipment. In an embodiment, current equipment used to align and bring together circuits to be stacked is used to align and bring together circuits to be stacked using metallic glass.

A method 200 may include preparing the surfaces of a first and second integrated circuit for bonding 202 prior to applying a bulk metallic glass bonding material to one or more pads 204. Preparing the surfaces 202 may include polishing, etching, or vapor deposition of the one or more pads to be joined, or suitable combinations thereof.

In an embodiment, a method 200 includes applying a post-bonding process 212 after stacking the first and second integrated circuits 210. In an embodiment, applying a post-bonding process 212 includes thinning a backside surface of the stacked integrated circuits, creating vias through the thinned surface and creating interconnect bumps onto the thinned surface of the stacked integrated circuit, and/or electrically coupling the stacked device with other packaging or assembly components through the created vias and interconnect bumps, or suitable combinations thereof. Thinning a backside surface may be performed until about 100 microns or less of semiconductor substrate remains between the backside surface and the integrated circuit. In another embodiment, wirebonding is used to couple the stacked device with other microelectronic devices.

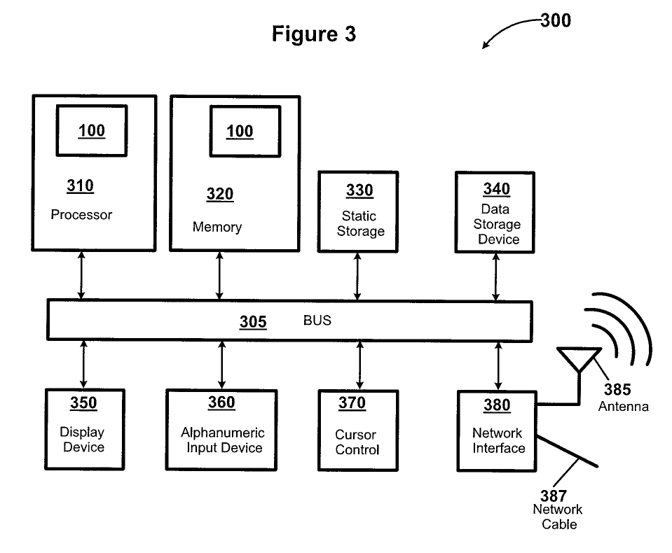

In another embodiment, applying a post-bonding process 212 includes stacking one or more additional integrated circuits with the stacked first and second integrated circuit, the one or more integrated circuits being stacked together with the first and second integrated circuits using bulk metallic glass as a bonding material. In other embodiments, a stacked integrated circuit formed using method 200 is coupled with other components, microelectronic devices, or electronic systems as depicted in FIG. 3, for example.

FIG. 3 is a diagram of an example system in which embodiments of the present invention may be used, according to but one embodiment. System 300 is intended to represent a range of electronic systems (either wired or wireless) including, for example, desktop computer systems, laptop computer systems, personal computers (PC), wireless telephones, personal digital assistants (PDA) including cellular-enabled PDAs, set top boxes, pocket PCs, tablet PCs, DVD players, or servers, but is not limited to these examples and may include other electronic systems. Alternative electronic systems may include more, fewer and/or different components.

In one embodiment, electronic system 300 includes stacked integrated circuits bonded using bulk glassy metal 100 in accordance with embodiments described with respect to FIGS. 1-2. In an embodiment, stacked integrated circuits bonded using bulk glassy metal 100 are part of an electronic system's memory 320 or processor 310.

Electronic system 300 may include bus 305 or other communication device to communicate information, and processor 310 coupled to bus 305 that may process information. While electronic system 300 may be illustrated with a single processor, system 300 may include multiple processors and/or co-processors. In an embodiment, processor 310 includes stacked logic integrated circuits 100 in accordance with embodiments described herein. System 300 may also include random access memory (RAM) or other storage device 320 (may be referred to as memory), coupled to bus 305 and may store information and instructions that may be executed by processor 310.

Memory 320 may also be used to store temporary variables or other intermediate information during execution of instructions by processor 310. Memory 320 is a flash memory device in one embodiment. In another embodiment, memory 320 includes stacked integrated circuits 100 formed using glassy metal bonding techniques 100, 200 disclosed herein.

System 300 may also include read only memory (ROM) and/or other static storage device 330 coupled to bus 305 that may store static information and instructions for processor 310. Data storage device 340 may be coupled to bus 305 to store information and instructions. Data storage device 340 such as a magnetic disk or optical disc and corresponding drive may be coupled with electronic system 300.

Electronic system 300 may also be coupled via bus 305 to display device 350, such as a cathode ray tube (CRT) or liquid crystal display (LCD), to display information to a user. Alphanumeric input device 360, including alphanumeric and other keys, may be coupled to bus 305 to communicate information and command selections to processor 310. Another type of user input device is cursor control 370, such as a mouse, a trackball, or cursor direction keys to communicate information and command selections to processor 310 and to control cursor movement on display 350.

Electronic system 300 further may include one or more network interfaces 380 to provide access to network, such as a local area network. Network interface 380 may include, for example, a wireless network interface having antenna 385, which may represent one or more antennae. Network interface 380 may also include, for example, a wired network interface to communicate with remote devices via network cable 387, which may be, for example, an Ethernet cable, a coaxial cable, a fiber optic cable, a serial cable, or a parallel cable.

In one embodiment, network interface 380 may provide access to a local area network, for example, by conforming to an Institute of Electrical and Electronics Engineers (IEEE) standard such as IEEE 802.11b and/or IEEE 802.11g standards, and/or the wireless network interface may provide access to a personal area network, for example, by conforming to Bluetooth standards. Other wireless network interfaces and/or protocols can also be supported.

IEEE 802.11b corresponds to IEEE Std. 802.11b-1999 entitled “Local and Metropolitan Area Networks, Part 11: Wireless LAN Medium Access Control (MAC) and Physical Layer (PHY) Specifications: Higher-Speed Physical Layer Extension in the 2.4 GHz Band,” approved Sep. 16, 1999 as well as related documents. IEEE 802.11g corresponds to IEEE Std. 802.11g-2003 entitled “Local and Metropolitan Area Networks, Part 11: Wireless LAN Medium Access Control (MAC) and Physical Layer (PHY) Specifications, Amendment 4: Further Higher Rate Extension in the 2.4 GHz Band,” approved Jun. 27, 2003 as well as related documents. Bluetooth protocols are described in “Specification of the Bluetooth System: Core, Version 1.1,” published Feb. 22, 2001 by the Bluetooth Special Interest Group, Inc. Previous or subsequent versions of the Bluetooth standard may also be supported.

In addition to, or instead of, communication via wireless LAN standards, network interface(s) 480 may provide wireless communications using, for example, Time Division, Multiple Access (TDMA) protocols, Global System for Mobile Communications (GSM) protocols, Code Division, Multiple Access (CDMA) protocols, and/or any other type of wireless communications protocol.

In an embodiment, a system 300 includes one or more omnidirectional antennae 385, which may refer to an antenna that is at least partially omnidirectional and/or substantially omnidirectional, and a processor 310 coupled to communicate via the antennae.

The above description of illustrated embodiments, including what is described in the Abstract, is not intended to be exhaustive or to limit to the precise forms disclosed. While specific embodiments and examples are described herein for illustrative purposes, various equivalent modifications are possible within the scope of this description, as those skilled in the relevant art will recognize.

These modifications can be made in light of the above detailed description. The terms used in the following claims should not be construed to limit the scope to the specific embodiments disclosed in the specification and the claims. Rather, the scope of the embodiments disclosed herein is to be determined entirely by the following claims, which are to be construed in accordance with established doctrines of claim interpretation.

What is claimed is:

1. An apparatus comprising:
a first integrated circuit having one or more bonding pads; and
a second integrated circuit having one or more bonding pads, the second integrated circuit being electrically and mechanically coupled with the first integrated circuit by one or more joints formed between the one or more bonding pads of the first and second integrated circuit using a bulk metallic glass bonding material, wherein the bulk metallic glass provides a low temperature and low pressure bonding solution to reduce delamination.

2. An apparatus according to claim 1 wherein the first and second IC are substantially aligned to enable electrical communication through the joints.

3. An apparatus according to claim 1 wherein the bulk metallic glass joint is amorphous, crystalline, or suitable combinations thereof.

4. An apparatus according to claim 1 wherein the first and second integrated circuits comprise stacked wafers, dies, or suitable combinations thereof.

5. An apparatus according to claim 1 wherein the low bonding temperature for the bulk metallic glass joint is less than about 200° C. and the low bonding pressure is less than about 5 MPa.

6. An apparatus according to claim 1 wherein the bulk metallic glass joint comprises Au_{49.2}Cu₂₇Ag_{5.5}Pd_{2.35}Si₁₆, Pt_{57.5}Cu_{14.7}Ni_{5.3}P_{22.5}, or Mg₆₅Cu₂₅Y₁₀, or suitable combinations thereof, where the numbers represent approximate atomic % and wherein the one or more pads comprise Cu.

7. An apparatus according to claim 1 wherein the bulk metallic glass joint is substantially free of reliability-threatening intermetallic compounds at the interface between the joint and the one or more pads of the first and second integrated circuits, wherein the bulk metallic glass provides reduced intermetallic compound to increase joint reliability.

8. An apparatus according to claim 1 further comprising:
one or more integrated circuits in addition to the first and second integrated circuits, the one or more integrated circuits being stacked together with the first and second integrated circuits using bulk metallic glass as a bonding material.

9. A method comprising:
applying a bulk metallic glass bonding material to one or more pads of a first integrated circuit or a second integrated circuit wherein the bulk metallic glass bonding material provides a low temperature and low pressure bonding solution to reduce delamination or wherein the bulk metallic glass provides reduced intermetallic compound to increase joint reliability, or suitable combinations thereof;
aligning the one or more pads of the first and second integrated circuits to prepare them for bonding;
bringing the surfaces of the one or more bonding pads within proximity of one another such that the one or more pads of the first and second integrated circuits are coupled via the bulk metallic glass bonding material; and
stacking the first and second integrated circuits by applying low heat and low pressure to form a joint between the first and second integrated circuits using the bulk metallic glass bonding material.

10. A method according to claim 9 further comprising:
preparing the surfaces of a first and second integrated circuit for bonding prior to applying a bulk metallic glass bonding material to one or more pads; and
applying a post-bonding process after stacking the first and second integrated circuits.

11. A method according to claim 10 wherein preparing the surfaces comprises polishing, etching, or vapor deposition of the one or more pads to be joined, or suitable combinations thereof and wherein applying a post-bonding process comprises thinning a surface of the stacked integrated circuits, creating vias through the thinned surface and creating interconnect bumps onto the thinned surface of the stacked integrated circuit, or electrically coupling the stacked device with other packaging or assembly components through the created vias and interconnect bumps, or suitable combinations thereof.

12. A method according to claim 10 wherein applying a post-bonding process comprises stacking one or more additional integrated circuits with the stacked first and second integrated circuit, the one or more integrated circuits being stacked together with the first and second integrated circuits using bulk metallic glass as a bonding material.

13. A method according to claim 9 wherein stacking the first and second integrated circuits comprises using a low bonding temperature for the bulk metallic glass that is less than about 200° C. and applying a low bonding pressure that is less than about 5 MPa.

14. A method according to claim 9, wherein applying a metallic glass bonding material comprises applying Au_{49.2}Cu₂₇Ag_{5.5}Pd_{2.35}Si₁₆, Pt_{57.5}Cu_{14.7}Ni_{5.3}P_{22.5}, or Mg₆₅Cu₂₅Y₁₀, or suitable combinations thereof, where the numbers represent approximate atomic % and wherein the one or more pads comprise Cu.

15. A method according to claim 9 wherein stacking the first and second integrated circuits comprises forming a bulk metallic glass joint having substantially no reliability-threatening intermetallic compounds at the interface between the joint and the one or more pads of the first and second integrated circuits.
